(19) United States
(12) Patent Application Publication
(10) Pub. No.: US 2020/0075836 A1
(43) Pub. Date: Mar. 5, 2020

(54) CAP AND PIEZOELECTRIC DEVICE

(71) Applicant: NIHON DEMPA KOGYO CO., LTD., Tokyo (JP)

(72) Inventors: Hiromi OKUBO, Saitama (JP); Shuichi MIZUSAWA, Saitama (JP)

(21) Appl. No.: 16/558,164

(22) Filed: Sep. 2, 2019

(30) Foreign Application Priority Data
Sep. 4, 2018 (JP) 2018-164986

(51) Int. Cl. H01L 41/053; H01L 41/47

(52) U.S. Cl. CPC H01L 41/053; H01L 41/47

(57) ABSTRACT

A cap made of metal includes a first surface, a second surface, and a third surface. The first surface includes an outer ceiling surface, an outer sidewall surface, and a flange outer peripheral end surface. The second surface includes an inner ceiling surface parallel to the outer ceiling surface and an inner sidewall surface parallel to the outer sidewall surface. The second surface is a side facing the base plate. The third surface connects the flange outer peripheral end surface to the inner sidewall surface. The third surface is bonded to the base plate with the eutectic alloy. The third surface includes a first curved surface having a first curvature from one end of the third surface to the flange outer peripheral end surface and a second curved surface having a second curvature from another end of the third surface to the inner sidewall surface.

### CROSS-REFERENCE TO RELATED APPLICATIONS

This application claims the priority benefits of Japanese Patent Application No. 2018-164986, filed on Sep. 4, 2018. The entirety of the above-mentioned patent application is hereby incorporated by reference herein and made a part of this specification.

### TECHNICAL FIELD

This disclosure relates to a cap made of metal that seals a piezoelectric element, and also relates to a piezoelectric device including the cap.

### DESCRIPTION OF THE RELATED ART

Piezoelectric devices, such as a piezoelectric filter, a piezoelectric resonator, a piezoelectric vibrating piece, a piezoelectric oscillator, and an acceleration sensor, using a piezoelectric material such as crystal are used in fields in an extremely wide range. One type of such piezoelectric devices is disclosed in, for example, Japanese Unexamined Patent Application Publication No. 2000-134055. This piezoelectric device includes a plate-shaped base plate and a metal cap. The base plate includes a bonding metal film formed of a metal film on a peripheral area. The metal cap has a dome shape where a peripheral area is bent downward, and a flange surface is formed on the peripheral area. The bonding metal film and the flange surface are sealed.

However, when an external pressure and the like is applied due to an insufficient sealing strength of the piezoelectric device, leakage possibly occurs between an inside of the piezoelectric device and external air. While enlarging the bonding metal film and the flange surface enhances a bonding strength of the base plate and the metal cap, this causes increase in size of the piezoelectric device.

A need thus exists for a cap and a piezoelectric device which are not susceptible to the drawback mentioned above.

### SUMMARY

According to an aspect of this disclosure, there is provided a cap made of metal for bonding to a base plate to which a piezoelectric element is installed with a eutectic alloy. The cap includes a first surface, a second surface, and a third surface. The first surface includes an outer ceiling surface, an outer sidewall surface, and a flange outer peripheral end surface. The outer ceiling surface has four sides and a rectangular shape. The outer sidewall surface is bent from the four sides of the outer ceiling surface. The flange outer peripheral end surface is formed outside the outer sidewall surface. The second surface includes an inner ceiling surface parallel to the outer ceiling surface and an inner sidewall surface parallel to the outer sidewall surface. The second surface is a side facing the base plate. The third surface connects the flange outer peripheral end surface to the inner sidewall surface. The third surface is bonded to the base plate with the eutectic alloy. The third surface includes a first curved surface having a first curvature from one end of the third surface to the flange outer peripheral end surface and a second curved surface having a second curvature from another end of the third surface to the inner sidewall surface.

### BRIEF DESCRIPTION OF THE DRAWINGS

The foregoing and additional features and characteristics of this disclosure will become more apparent from the following detailed description considered with reference to the accompanying drawings.

FIG. 1 is an exploded perspective view of a piezoelectric device 100.

FIG. 2A is a sectional drawing of a cap made of metal and its partially enlarged figure.

FIG. 2B is a partially enlarged figure of the cap made of metal and a modification of FIG. 2A.

FIG. 3 is a sectional drawing of the piezoelectric device.

FIGS. 4A and 4B are enlarged sectional drawings of a bonding metal film and a flange surface.

### DESCRIPTION OF EMBODIMENTS

The following describes an embodiment of the disclosure with reference to the drawings. Each drawing used in the descriptions is merely illustrated schematically for understanding the embodiment, and a size, an angle, a thickness or similar factor is exaggeratedly illustrated. In each drawing used in the descriptions, like reference numerals designate corresponding or identical elements, and therefore such elements will not be further elaborated in some cases. Shapes, dimensions, materials, and similar factor described in the following embodiment are merely preferable examples within the scope of the disclosure.

[Configuration of Piezoelectric Device 100]

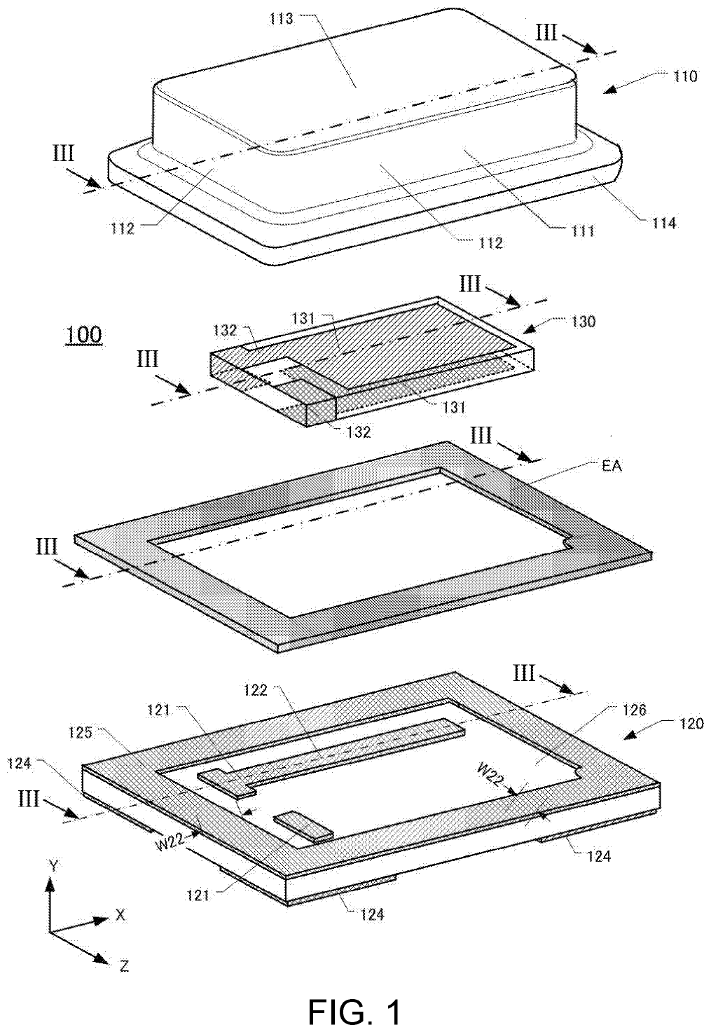

FIG. 1 is an exploded perspective view of the piezoelectric device 100. The piezoelectric device 100 includes a cap 110 made of metal, a ceramic base plate 120, and a piezoelectric vibrating piece 130. For the piezoelectric vibrating piece 130, for example, a quartz-crystal vibrating piece of AT-cut, SC-cut, or similar cut is used. While the following representatively describes the quartz-crystal vibrating piece, this embodiment is applicable to the piezoelectric device using a piezoelectric piece for a crystal filter and a piezoelectric material other than a crystal. The description will be given while defining a longitudinal direction of the piezoelectric device 100 as an X-axis direction, a height direction of the piezoelectric device 100 as a Y-axis direction, and a direction perpendicular to the X-axis direction and the Y-axis direction as a Z-axis direction.

In the piezoelectric device 100, the piezoelectric vibrating piece 130 is placed on a surface of a +Y-axis side of the ceramic base plate 120. Further, the cap 110 made of metal is placed on the surface of the +Y-axis side of the ceramic base plate 120 so as to seal the piezoelectric vibrating piece 130. The ceramic base plate 120 and the cap 110 made of metal are bonded via a eutectic alloy EA as a bonding agent. The piezoelectric device 100 is a surface mount type piezoelectric device mounted to a printed circuit board and the like. While FIG. 1 illustrates the eutectic alloy EA as the bonding agent in a flat plate frame shape, the eutectic alloy EA is disposed on at least one of a flange surface or a bonding metal film described later.

The cap 110 made of metal is pressed with a mold (not illustrated) to be formed in a box shape having a depressed portion 111 depressed in a +Y-axis direction. The cap 110 made of metal has four wall plates 112 that surround the depressed portion 111, a top board 113 bonded to sides on the +Y-axis sides of the respective wall plates 112, and a flange portion 114 formed in a ring shape on sides on −Y-axis sides of the respective wall plates 112 so as to be bent outward from the wall plates 112.

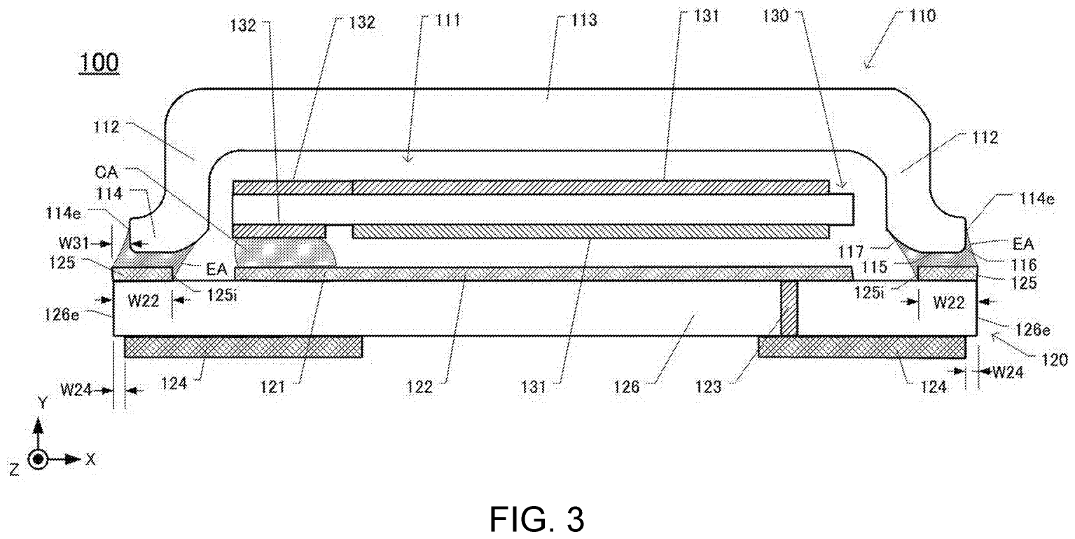

The ceramic base plate 120 has a rectangular shape in plan view, and includes a flat plate 126 that has upper and lower principal surfaces. The ceramic flat plate 126 includes a pair of connection pads 121 on a surface of a +Y-axis side. The connection pads 121 are each electrically connected to the piezoelectric vibrating piece 130 via a conductive adhesive CA (see FIG. 3). The ceramic base plate 120 includes four mounting terminals 124 on a surface of a −Y-axis side. The ceramic flat plate 126 includes a pair of through electrodes 123 (see FIG. 3) passing through in the Y-axis direction. The respective connection pads 121 are electrically connected to the mounting terminals 124 via the through electrodes 123 or via a wiring electrode 122 and the through electrodes 123. The four mounting terminals 124 are disposed in this embodiment. One of the four mounting terminals 124 may be a grounding terminal. The piezoelectric device 100 is mounted to the printed circuit board and the like via the mounting terminal 124 with a solder or the like.

A frame-shaped bonding metal film 125 is formed on an outer peripheral side on the surface of the +Y-axis side of the flat plate 126 so as to surround the whole electrodes formed on the surface of the +Y-axis side of the ceramic base plate 120. This frame-shaped bonding metal film 125 faces the flange portion 114, and the bonding metal film 125 is bonded to the flange portion 114 with the eutectic alloy EA. The frame-shaped bonding metal film 125 is formed from a position of an outer peripheral end 126e of the flat plate 126 having a width W22. The frame-shaped bonding metal film 125 has an outer peripheral end at a position matching the position of the outer peripheral end 126e of the flat plate 126. The connection pads 121, the wiring electrode 122, and the frame-shaped bonding metal film 125 are formed by screen-printing and the like. The bonded bonding metal film 125 has a thickness (Y-axis direction) of about 10 μm. While a description is given using the ceramic base plate in the first embodiment, the base plate may be formed of glass or crystal.

The piezoelectric vibrating piece 130 includes excitation electrodes 131 on the surfaces of the +Y-axis side and the −Y-axis side, and extraction electrodes 132 are extracted from the respective excitation electrodes 131. The extraction electrode 132 is extracted from the excitation electrode 131 formed on the surface of the +Y-axis side of the piezoelectric vibrating piece 130 to the −X-axis side, and the extraction electrode 132 is further extracted to the surface of the −Y-axis side via a side surface of a −Z-axis side of the piezoelectric vibrating piece 130. The extraction electrode 132 extracted from the excitation electrode 131 formed on the surface of the −Y-axis side of the piezoelectric vibrating piece 130 extends from the excitation electrode 131 to the −X-axis side, and is further extracted to the surface of the +Y-axis side via a side surface of the +Z-axis side of the piezoelectric vibrating piece 130.

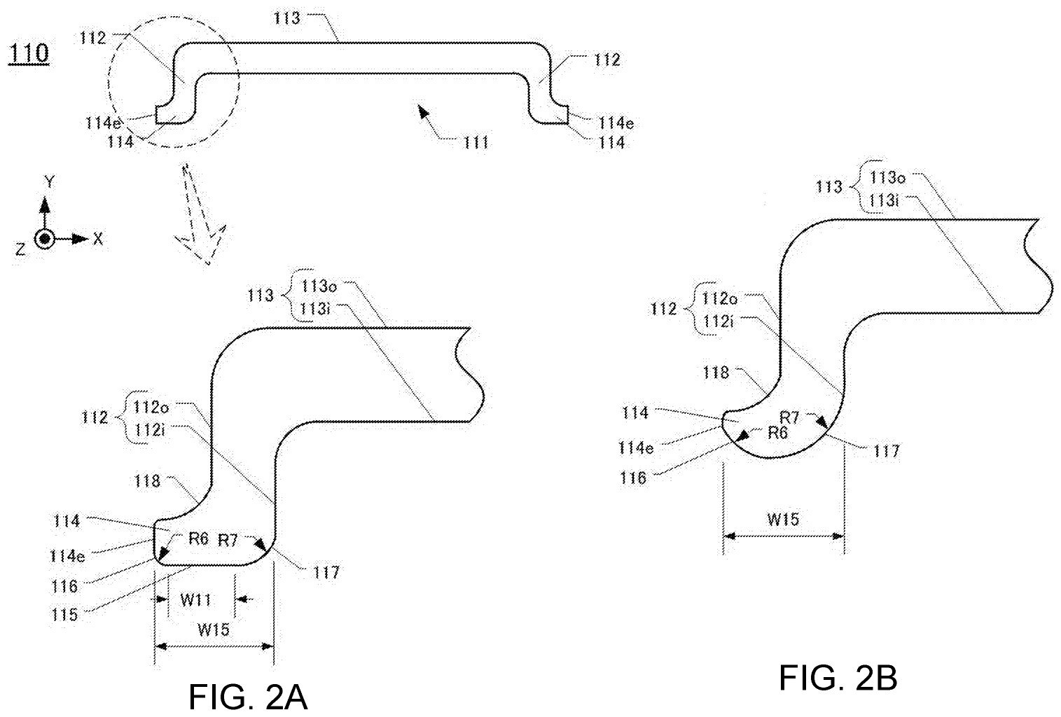

FIG. 2A is a sectional drawing of the cap made of metal taken along a line III-III of FIG. 1 and an enlarged figure of a periphery of the flange portion. The cap 110 made of metal is bonded to a top surface of the base plate 120 with the eutectic alloy EA to airtightly seal the piezoelectric vibrating piece 130 mounted on the top surface of the base plate 120.

The cap 110 made of metal is made of an alloy, for example, containing at least any of iron, nickel, or cobalt, and integratedly formed. The cap 110 made of metal airtightly seals the depressed portion 111 in a vacuum state or the depressed portion 111 where nitrogen gas or the like is filled. The top board 113 has a rectangular flat plate shape in plan view, and has a principal surface larger than the principal surface of the rectangular-shaped piezoelectric vibrating piece 130 and smaller than the top surface of the base plate 120 in size. The top board 113 has a lower side on which the depressed portion 111 surrounded by the top board 113 and the four wall plates 112 is formed.

The wall plates 112 form the depressed portion 111 on the lower surface of the cap 110 made of metal, and are disposed along an outer edge of the top board 113. In the depressed portion 111, the piezoelectric vibrating piece 130 mounted on the base plate 120 is housed. The flange portion 114 ensures an area for bonding the cap 110 made of metal and the base plate 120 to enhance a bonding strength. The flange portion 114 extends along outer peripheral surfaces of the wall plates 112 in an annular shape and from lower ends toward outer peripheral sides of the wall plates 112.

A dimension of the completed cap 110 made of metal, especially, a dimension of the periphery of the flange portion 114 will be described with reference to the enlarged figure of FIG. 2A. As illustrated in the enlarged figure, the top board 113 includes an outer ceiling surface 113o and an inner ceiling surface 113i. The outer ceiling surface 113o and the inner ceiling surface 113i are mutually parallel. The wall plate 112 has an outer sidewall surface 112o and an inner sidewall surface 112i. The outer sidewall surface 112o and the inner sidewall surface 112i are mutually parallel.

A part from the wall plate 112 to the flange portion 114 is bent outward at a right angle. At its corner, an inner bent surface 117 (second curved surface 117) and an outer bent surface 118 are formed on an inside and an outside. The inner bent surface 117 is a curved surface continuous from the inner sidewall surface 112i and preferred to have a large curvature such that a fillet of the eutectic alloy EA is easily formed as described later. The bent surface 118 is a curved surface from the outer sidewall surface 112o to an outer peripheral end surface 114e of the flange portion 114, and formed not to have long lengths in the Z-axis direction and the Y-axis direction of the cap 110 made of metal. That is, on the upper side (+Y-axis side) of the flange portion 114, there is almost no plane area (XZ-plane) preferably.

On the lower side (−Y-axis side) of the flange portion 114, a flange plane (XZ-plane) 115 having a width W11 is formed. A first curved surface 116 having a first curvature is formed from one end of the flange plane 115 to the outer peripheral end surface 114e of the flange portion 114. The flange plane 115 has the other end connected to the inner bent surface 117. In this embodiment, an outer side surface, which contacts external air, of the cap 110 made of metal includes the outer ceiling surface 113o, the outer sidewall surface 112o, the outer bent surface 118, and the outer peripheral end surface 114e of the flange portion 114. On the outer side surface, at least the outer ceiling surface 113o and the outer sidewall surface 112o configures a first surface. The cap 110 made of metal has an inner side surface (second surface) on which the piezoelectric vibrating piece 130 is disposed. The inner side surface includes the inner ceiling surface 113i and the inner sidewall surface 112i. The cap 110 made of metal has a third surface that is bonded to the base plate 120 with the eutectic alloy EA. The third surface includes the flange plane 115, the first curved surface 116, and the inner bent surface 117 (second curved surface 117).

Provisionally, when the base plate 120 has the length in the X-axis direction of 0.80 mm and the length in the Z-axis direction of 0.60 mm, the flange plane 115 has the width W11 of 0.03 mm (30 μm) to 0.07 mm (70 μm), preferably about 0.05 mm. The first curved surface 116 has a curvature radius R6 of 0.005 mm (5 μm) to 0.020 mm (20 μm), and preferably about 0.012 mm (12 μm). The inner bent surface 117 has a curvature radius R7 of 0.015 mm (15 μm) to 0.035 mm (35 μm), approximately ½ of the width W11 of the flange plane 115, and preferably about 0.025 mm (25 μm). Therefore, a width W15 from the outer peripheral end surface 114e of the flange portion 114 to the inner sidewall surface 112i of the wall plate 112 is preferably 0.050 mm (50 μm) to 0.125 mm (125 μm).

FIG. 2B is an enlarged figure of the periphery of the flange portion taken along a line III-III of FIG. 1 and a modification of the flange portion illustrated in FIG. 2A. The flange portion illustrated in FIG. 2A and the flange portion illustrated in FIG. 2B are different in that the flange portion in FIG. 2B does not include the flange plane 115. That is, on the lower side (−Y-axis side) of the flange portion 114, the first curved surface 116 having the first curvature is formed from the outer peripheral end surface 114e of the flange portion 114, the bent surface (second curved surface) 117 is formed from the first curved surface 116, and the bent surface 117 is connected to the inner sidewall surface 112i. The curvature radius R6 of the first curved surface 116 and the curvature radius R7 of the bent surface 117 are larger than those of the flange portion illustrated in FIG. 2A. On the other hand, the width W15 from the outer peripheral end surface 114e of the flange portion 114 to the inner sidewall surface 112i of the wall plate 112 is identical to that of the flange portion in FIG. 2A. It is also identical that the outer side surface of the cap 110 made of metal includes the outer ceiling surface 113o, the outer sidewall surface 112o, the outer bent surface 118, and the outer peripheral end surface 114e. Further, it is also identical that the inner side surface of the cap 110 made of metal includes the inner ceiling surface 113i and the inner sidewall surface 112i. However, since the curvature radius R7 of the bent surface 117 becomes large, the inner sidewall surface 112i has a slightly short length.

Here, a method for manufacturing the cap 110 made of metal will be described. The cap 110 made of metal is manufactured by, for example, performing a plastic work on a flat plate by a presswork using a mold. The top board 113, the wall plates 112, and the flange portion 114 are formed by sandwiching and applying pressure to a flat plate with a pair of molds having a protruding part and a depressed part in a shape identical to that of the depressed portion 111 of the cap 110 made of metal. Afterwards, sand-blasting or the like is performed to increase a curvature of bending especially at the periphery of the flange portion 114, and Burrs caused in the presswork are removed. The sand-blasting or the like finishes the first curved surface 116 having the curvature radius R6 of 5 μm to 20 μm. Bending by the presswork and the sand-blasting or the like finish the second curved surface 117 having the curvature radius R7 of 15 μm to 35 μm.

FIG. 3 is a sectional drawing of the piezoelectric device taken along the line III-III of FIG. 1. The piezoelectric vibrating piece 130 is placed on the surface of the +Y-axis side of the ceramic base plate 120. The extraction electrode 132 of the piezoelectric vibrating piece 130 is electrically connected to the connection pad 121 of the ceramic base plate 120 via the conductive adhesive CA. The excitation electrode 131 of the piezoelectric vibrating piece 130 is electrically connected to the mounting terminal 124 via the wiring electrode 122 and the through electrode 123. Then, the frame-shaped bonding metal film 125 is formed to have the width W22 from the outer peripheral end 126e of the flat plate 126 to an inner end 125i inside the bonding metal film 125. Provisionally, when the base plate 120 has the length in the X-axis direction of 0.80 mm and the length in the Z-axis direction of 0.60 mm, the frame-shaped bonding metal film 125 has the width W22 of 0.06 mm to 0.08 mm. The mounting terminal 124 is formed to be separated from the outer peripheral end 126e of the flat plate 126 by a width W24, for example, 0.02 mm.

A length of the cap 110 made of metal, that is, a length from one outer peripheral end surface 114e of the flange portion 114 to the other outer peripheral end surface 114e is shorter than a length from one outer peripheral end 126e of the flat plate 126 to the other outer peripheral end 126e. In the X-axis direction illustrated in FIG. 3, the length in the X-axis direction of the cap 110 made of metal is shorter than the length in the X-axis direction of the ceramic base plate 120 by a length about double of a width W31. In other words, the width W31 is a length from the outer peripheral end 126e of the flat plate 126 to the outer peripheral end surface 114e of the flange portion 114, and an outer peripheral end of the base plate 120 is positioned outside an outer peripheral end of the cap 110 made of metal in the X-axis direction.

As described above, the flange plane 115 of the cap 110 has the width W11 of 0.03 mm (30 μm) to 0.07 mm (70 μm), preferably about 0.05 mm (50 μm). Meanwhile, the frame-shaped bonding metal film 125 has the width W22 of 0.06 mm (60 μm) to 0.08 mm (80 μm). That is, the width W22 of the frame-shaped bonding metal film 125 is preferred to be greater than the width W11 of the flange plane 115. This is for easily forming the fillet (shape spreading toward the end formed by the molten bonding agent) of the eutectic alloy EA on the flange portion 114 of the cap 110.

Here, a description will be given of a positional relation between an inner end of the flange plane 115 of the cap 110 and an inner end of the frame-shaped bonding metal film 125. The flange plane 115 has an inner end 115i arranged on a position approximately identical to that of the inner end 125i of the frame-shaped bonding metal film 125. Alternatively, the inner end 125i of the frame-shaped bonding metal film 125 is preferred to be arranged outside the inner end 115i of the flange plane 115. This is also for easily forming the fillet of the eutectic alloy EA on the flange portion 114 of the cap 110, and for easily forming the fillet of the eutectic alloy EA on the inner end 125i of the frame-shaped bonding metal film 125. For such a positional relation, the width W15 from the inner sidewall surface 112i of the cap 110 to the outer peripheral end surface 114e is preferred to be greater than the width W22 of the bonding metal film 125.

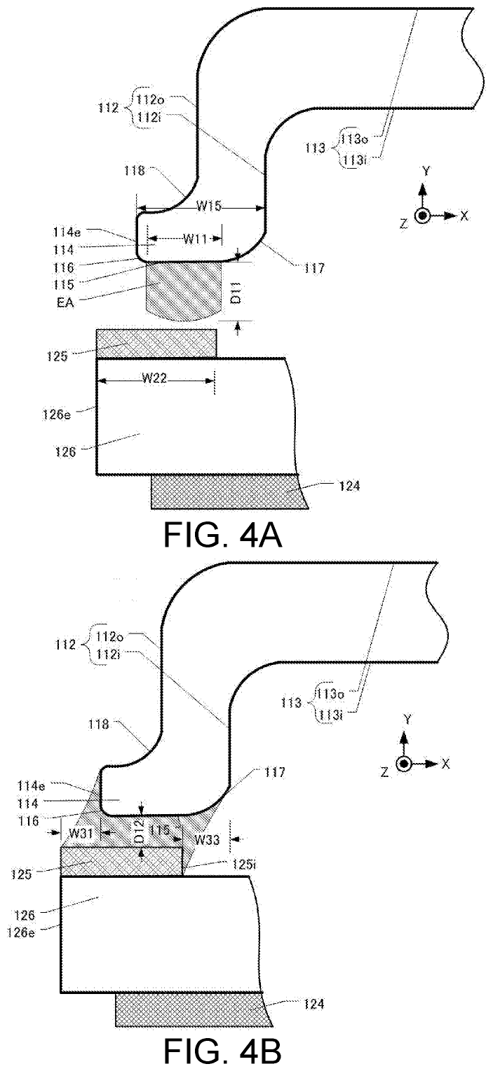

FIGS. 4A and 4B are partially enlarged figures of the flange surface of the cap made of metal and the base plate of FIG. 3. FIG. 4A is a drawing illustrating a state where the eutectic alloy EA is disposed on the flange plane 115 of the cap 110 made of metal and before this cap 110 made of metal is placed on the base plate 120. FIG. 4B is a drawing illustrating a state after this cap 110 made of metal is placed on the base plate 120. While the illustration is omitted, the eutectic alloy EA may be disposed on not the flange plane 115 of the cap 110 made of metal but the frame-shaped bonding metal film 125, or the eutectic alloy EA may be disposed on both of them.

The eutectic alloy EA has a melting point higher than a melting point 250° C. to 280° C. of an alloy (for example, lead-free solder) used for connecting the mounting terminal 124 to an external board of external electronic equipment and the like. For the eutectic alloy EA, for example, a zinc-aluminum (ZnAl) alloy, a gold-tin (AuSn) alloy, or a copper-tin (CuSn) alloy having the melting point above 300° C. (melting point above 400° C. after made to be an alloy) is preferable. The disposed eutectic alloy EA has a thickness D11 of, for example, 12 to 15 μm.

In sealing the cap 110 and the base plate 120, the flange portion 114 is placed on the frame-shaped bonding metal film 125, and the cap 110 and the base plate 120 are put into a predetermined sealing device. Then, when the eutectic alloy EA melts, the melted eutectic alloy EA flows in an outer peripheral direction of the bonding metal film 125 to make a thickness D12 of the eutectic alloy EA about 10 μm as illustrated in FIG. 4B. The melted eutectic alloy EA climbs up to the outer peripheral end surface 114e of the flange portion 114 via the first curved surface 116, and the fillet of the eutectic alloy EA is formed. Further, the melted eutectic alloy EA mounts also the inner bent surface (second curved surface) 117, and the fillet of the eutectic alloy EA is formed. Furthermore, the melted eutectic alloy EA is pulled by the eutectic alloy EA mounting the inner bent surface (second curved surface) 117, and then the fillet of the eutectic alloy EA is formed also on the inner end 125i of the bonding metal film 125. Accordingly, the cap 110 made of metal and the frame-shaped bonding metal film 125 are strongly sealed, thus the piezoelectric vibrating piece 130 is sealed in the depressed portion 111.

As described above, the length from the one outer peripheral end surface 114e of the flange portion 114 to the other outer peripheral end surface 114e is shorter than the length from the one outer peripheral end 126e of the flat plate 126 to the other outer peripheral end 126e by the length double of the width W31. On one side in the X-axis direction or the Z-axis direction, the width W31 is about ½ to ¼ of the width W22 of the frame-shaped bonding metal film 125. In view of this, in other words, the length of the cap 110 made of metal is shorter than the length of the ceramic base plate 120 by a length about one time to ½ of the width W22 of the frame-shaped bonding metal film 125. Provisionally, when the base plate 120 has the length in the X-axis direction of 0.80 mm and the length in the Z-axis direction of 0.60 mm, the width W31 is preferred to be 0.04 mm (40 μm) to 0.01 mm (10 μm), and further, the width W31 is further preferred to be 0.03 mm (30 μm) to 0.02 mm (20 μm). More preferably, the width W31 is about 0.025 mm (25 μm).

Next, a width W33 from the inner end 125i of the frame-shaped bonding metal film 125 to the inner sidewall surface 112i of the cap 110 made of metal will be described. As described above, the inner end 125i of the frame-shaped bonding metal film 125 is preferred to be positioned at a position approximately identical to or outside the position of the inner end 115i of the flange plane 115. In view of this, the width W33 from the inner end 125i of the frame-shaped bonding metal film 125 to the inner sidewall surface 112i of the cap 110 made of metal is longer than the width W31 from the outer peripheral end 126e of the flat plate 126 to the outer peripheral end surface 114e of the flange portion 114.

While the base plate described in this embodiment does not include castellation electrodes on four corners, this embodiment is also applicable to a base plate including a castellation electrode. This embodiment is also applicable to a base plate where an upper ceramic plate and a lower ceramic plate are combined and a through electrode and a castellation electrode are included.

In the above-described aspect of this disclosure, the third surface of the cap may include a third plane parallel to the base plate between the first curved surface and the second curved surface. The second curvature radius may be from 15 μm to 35 μm. The first curvature radius may be from 5 μm to 20 μm.

The cap made of metal according to the embodiment of the disclosure ensures the enhanced bonding strength of the base plate without increase in size.

The principles, preferred embodiment and mode of operation of the present invention have been described in the foregoing specification. However, the invention which is intended to be protected is not to be construed as limited to the particular embodiments disclosed. Further, the embodiments described herein are to be regarded as illustrative rather than restrictive. Variations and changes may be made by others, and equivalents employed, without departing from the spirit of the present invention. Accordingly, it is expressly intended that all such variations, changes and equivalents which fall within the spirit and scope of the present invention as defined in the claims, be embraced thereby.

What is claimed is:

1. A cap made of metal for bonding to a base plate to which a piezoelectric element is installed with a eutectic alloy, the cap comprising:
a first surface that includes an outer ceiling surface, an outer sidewall surface, and a flange outer peripheral end surface, wherein the outer ceiling surface has four sides and a rectangular shape, the outer sidewall surface is bent from the four sides of the outer ceiling surface, and the flange outer peripheral end surface is formed outside the outer sidewall surface;
a second surface that includes an inner ceiling surface parallel to the outer ceiling surface and an inner sidewall surface parallel to the outer sidewall surface, wherein the second surface is a side facing the base plate; and
a third surface that connects the flange outer peripheral end surface to the inner sidewall surface, wherein the third surface is bonded to the base plate with the eutectic alloy,
wherein the third surface includes:
a first curved surface having a first curvature from one end of the third surface to the flange outer peripheral end surface; and
a second curved surface having a second curvature from another end of the third surface to the inner sidewall surface.

2. The cap according to claim 1, wherein
the third surface includes: a flange plane parallel to the base plate between the first curved surface and the second curved surface.

3. The cap according to claim 1, wherein
a second curvature radius of the second curved surface is from 15 μm to 35 μm.

4. The cap according to claim 1, wherein
a first curvature radius of the first curved surface is from 5 μm to 20 μm.

5. A piezoelectric device, comprising:
the cap according to claim 1; and
a base plate on which a piezoelectric vibrating piece is placed.
